(19) United States
(12) Patent Application Publication
(10) Pub. No.: US 2006/0268593 A1
(43) Pub. Date: Nov. 30, 2006

(54) Read-only memory array with dielectric breakdown programmability

(75) Inventors: Meng Ding, Sunnyvale, CA (US); Zhizheng Liu, San Jose, CA (US); Yi He, Fremont, CA (US); Mark Randolph, San Jose, CA (US)

Correspondence Address: FARJAMI & FARJAMI LLP, Suite 360, 26522 La Alameda Avenue, Mission Viejo, CA, 92691, US

(73) Assignee: SPANSION LLC

(21) Appl. No.: 11/136,981

(22) Filed: May 25, 2005

(51) Int. Cl. G11C 17/00

(52) U.S. Cl. 365/94

(57) ABSTRACT

According to one exemplary embodiment, a programmable ROM array includes at least one bitline situated in a substrate. The programmable ROM array further includes at least one wordline situated over the at least one bitline. The programmable ROM array further includes a memory cell situated at an intersection of the at least one bitline and the at least one wordline, where the memory cell includes a dielectric region situated between the at least one bitline and the at least one wordline. A programming operation causes the memory cell to change from a first logic state to a second logic state by causing the dielectric region to break down. The programming operation causes the memory cell to operate as a diode. A resistance of the memory cell can be measured in a read operation to determine if the memory cell has the first or second logic state.

### TECHNICAL FIELD

The present invention is generally in the field of semiconductor devices. More particularly, the present invention is in the field of memory arrays.

### BACKGROUND ART

Non-volatile memory arrays are currently in use in a wide variety of electronic devices that require the retention of information when electrical power is terminated. Non-volatile memory arrays include read-only memory (ROM) arrays, such as semiconductor ROM arrays. Semiconductor ROM arrays, which are widely used in computer hardware and data storage systems, provide advantages such as high scalability, high density, and high performance.

ROM arrays include programmable ROM arrays, which are used in applications such as Field Programmable Gate Arrays (FPGA). A programmable ROM array is a ROM array that can be programmed only one time. However, after data has been written to the programmable ROM array during a programming operation, the data in the programmable ROM array can be read many times. As electronic devices that use programmable ROM arrays continue to decrease in size and price and increase in functionality, there is an increasing demand for programmable ROM arrays that have high scalability, performance, and density and are cost effective to manufacture.

Thus, there is a need in the art for a cost-effective programmable ROM array that also provides high scalability, performance, and density.

### SUMMARY

The present invention is directed to read-only memory array with dielectric breakdown programmability. The present invention addresses and resolves the need in the art for a cost-effective programmable ROM array that also provides high scalability, performance, and density.

According to one exemplary embodiment, a programmable ROM array includes at least one bitline situated in a substrate. The at least one bitline can be a P type semiconductor, for example. The programmable ROM array further includes at least one wordline situated over the at least one bitline. The at least one wordline can be an N type semiconductor. For example, the N type semiconductor can have an N type dopant concentration of between approximately 1.0×10¹⁸ cm⁻³ and approximately 1.0×10²⁰ cm⁻³. The programmable ROM array further includes a memory cell situated at an intersection of the at least one bitline and the at least one wordline, where the memory cell includes a dielectric region situated between the at least one bitline and the at least one wordline.

According to this exemplary embodiment, the dielectric region may have a thickness of between approximately 50.0 Angstroms and approximately 200.0 Angstroms, for example. The dielectric region includes a single layer of dielectric material, which may be silicon oxide, aluminum oxide, hafnium oxide, silicon nitride, zirconium oxide, or titanium oxide, for example. The dielectric region can also include multiple layers of dielectrics. In one embodiment, the dielectric region may be an ONO stack. A programming operation causes the memory cell to change from a first logic state to a second logic state by causing the dielectric region to break down. A difference between a first voltage applied to the at least one wordline and a second voltage applied to the at least one bitline during the programming operation causes the dielectric region to break down.

After the dielectric region has been broken down during the programming operation, the memory cell operates as a diode. A resistance of the memory cell can be measured in a read operation to determine if the memory cell has the first logic state or the second logic state. Other features and advantages of the present invention will become more readily apparent to those of ordinary skill in the art after reviewing the following detailed description and accompanying drawings.

### BRIEF DESCRIPTION OF THE DRAWINGS

FIG. 1 illustrates a top view of an exemplary structure including an exemplary programmable read-only memory array, in accordance with one embodiment of the present invention.

FIG. 2 illustrates a cross-sectional view along the line 2-2 in FIG. 1 of the structure of FIG. 1.

FIG. 3 illustrates a diagram of an exemplary memory cell after a programming operation, in accordance with one embodiment of the present invention.

FIG. 4 is a graph showing an exemplary I-V curve for an exemplary memory cell in accordance with one with one embodiment of the present invention.

### DETAILED DESCRIPTION OF THE INVENTION

The present invention is directed to read-only memory array with dielectric breakdown programmability. The following description contains specific information pertaining to the implementation of the present invention. One skilled in the art will recognize that the present invention may be implemented in a manner different from that specifically discussed in the present application. Moreover, some of the specific details of the invention are not discussed in order not to obscure the invention.

The drawings in the present application and their accompanying detailed description are directed to merely exemplary embodiments of the invention. To maintain brevity, other embodiments of the present invention are not specifically described in the present application and are not specifically illustrated by the present drawings. It should be borne in mind that, unless noted otherwise, like or corresponding elements among the figures may be indicated by like or corresponding reference numerals.

The present invention provides an innovative programmable ROM array that can be programmed by breaking down dielectric regions in selected respective memory cells. Although an exemplary programmable ROM array having wordlines comprising an N type semiconductor and bitlines comprising a P type semiconductor is utilized to illustrate the invention, the present invention can also be applied to a programmable ROM array having wordlines comprising a P type semiconductor and bitlines comprising an N type semiconductor.

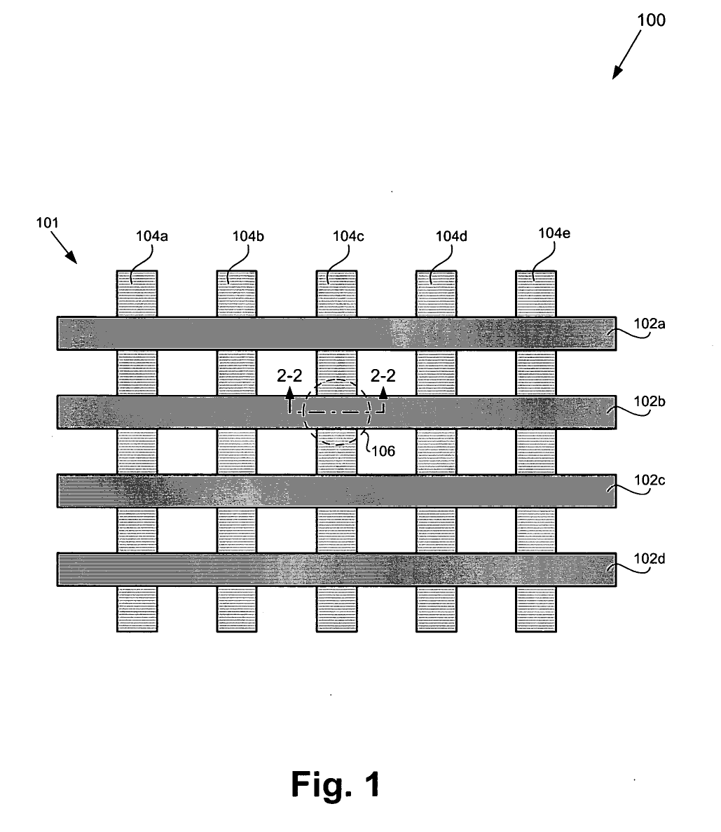

FIG. 1 shows a top view of an exemplary structure including an exemplary memory cell in accordance with one embodiment of the present invention. Structure 100 includes programmable ROM array 101, which is situated on a silicon substrate (not shown in FIG. 1). Programmable ROM array 101 includes wordlines 102a, 102b, 102c, and 102d, bitlines 104a, 104b, 104c, 104d, and 104e, and memory cell 106. It is noted that although only memory cell 106 is described in detail herein to preserve brevity, programmable ROM array 101 includes a number of memory cells, which are substantially similar to memory cell 106 in composition and manner of fabrication. These memory cells are situated at each respective intersection of a wordline (e.g. wordlines 102a-102d) and a bitline (e.g. bitlines 104a-104e).

As shown in FIG. 1, wordlines 102a, 102b, 102c, and 102d are situated over and aligned perpendicular to bitlines 104a, 104b, 104c, 104d, and 104e. Wordlines 102a, 102b, 102c, and 102d can comprise an N type semiconductor and can be fabricated in a manner known in the art. The N type semiconductor can comprise, for example, polycrystalline silicon, which can be heavily doped with arsenic or other appropriate N type dopant. By way of example, wordlines 102a, 102b, 102c, and 102d can have an N+ type dopant concentration of between approximately 1.0×10¹⁸ cm⁻³ and approximately 1.0×10²⁰ cm⁻³. By way of example, wordlines 102a, 102b, 102c, and 102d can have a thickness of between approximately 1000.0 Angstroms and approximately 2000.0 Angstroms.

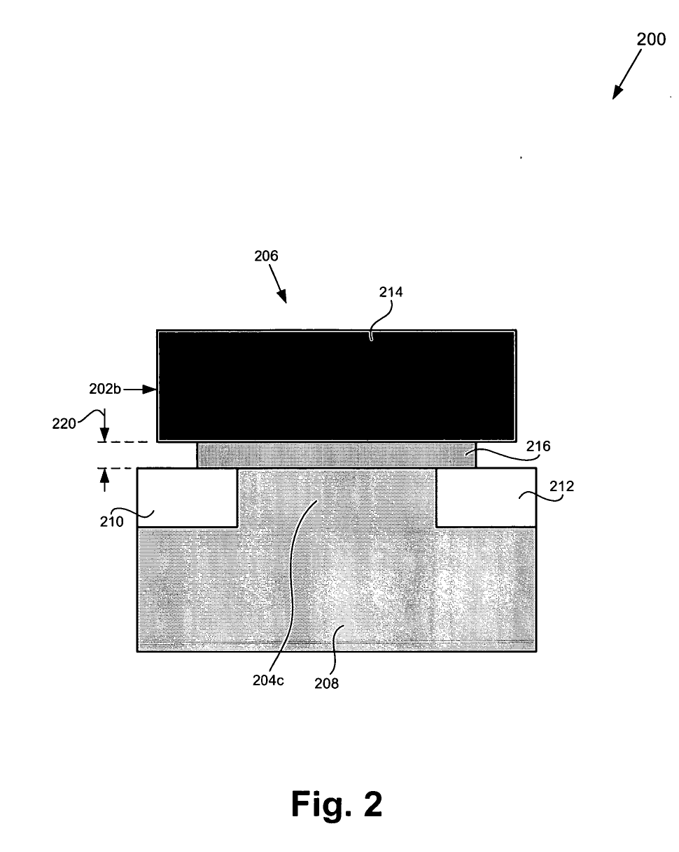

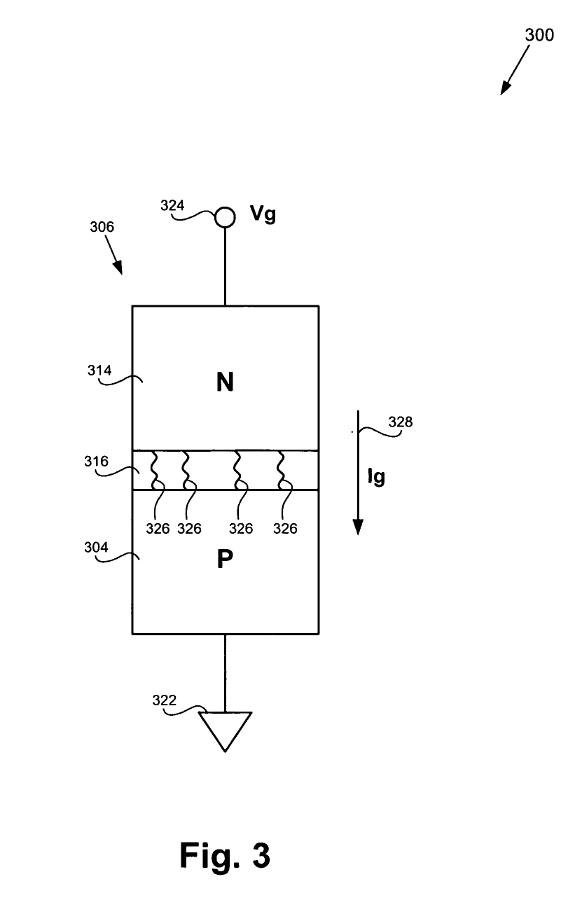

Bitlines 104a, 104b, 104c, 104d, and 104e are situated in a silicon substrate (not shown in FIG. 1) and can comprise a P type semiconductor. The P type semiconductor can comprise silicon, which can be doped with boron or other appropriate P type dopant. In one embodiment, bitlines 104a, 104b, 104c, 104d, and 104e can comprise a P+ (i.e. a heavily doped P type) diffusion region. Also shown in FIG. 1, memory cell 106 is situated at the intersection of wordline 102b and bitline 104c. Memory cell 106 includes a dielectric region (not shown in FIG. 1), which is situated between wordline 102b and bitline 104c. The logic state of memory cell 106 is defined by the resistance of memory cell 106 as measured between wordline 102b and bitline 104c. In the present invention, the logic state of memory cell 106 is changed from a logic state, such as a logic “0” state, to an opposite logic state, such as a logic “1” state, by breaking down the dielectric region (not shown in FIG. 1) of memory cell 106 during a programming process (i.e. a write operation). Memory cell 206, which is an exemplary memory cell in the present invention's innovative programmable ROM array (e.g. programmable ROM array 101), will be discussed below in relation to FIGS. 2 and 3.

Structure 200 in FIG. 2 corresponds to a cross-sectional view of structure 100 along line 2-2 in FIG. 1. In particular, wordline 202b, bitline 204c, and memory cell 206 in structure 200 correspond, respectively, to wordline 102b, bitline 104c, and memory cell 106 in structure 100. Structure 200 includes wordline 202b, bitline 204c, memory cell 206, substrate 208, and isolation regions 210 and 212. Memory cell 206 includes wordline segment 214 and dielectric region 216.

As shown in FIG. 2, bitline 204c is situated in substrate 208, which can be a P type silicon substrate. Bitline 204c is also situated between isolation regions 210 and 212, which can comprise shallow trench isolation (STI) regions. In other embodiments, isolation regions 210 and 212 may comprise local oxidation of silicon (LOCOS) or other appropriate isolation material. Bitline 204c comprises P type silicon (i.e. a P type semiconductor). Also shown in FIG. 2, dielectric region 216 is situated over substrate 208 and over bitline 204c. In the present embodiment, dielectric region 216 can be a single dielectric layer comprising silicon oxide (SiO₂), aluminum oxide (Al₂O₃), hafnium oxide (HfO₂), silicon nitride (Si₃N₄), zirconium oxide (ZrO₂), titanium oxide (TiO₂), or other appropriate dielectric material. In other embodiments, dielectric region 216 can be a dielectric stack comprising SiO₂ and Si₃N₄ (e.g. a two dielectric layer stack), SiO₂/Si₃N₄/SiO₂ (i.e. an Oxide-Nitride-Oxide (ONO) stack) (e.g. a three dielectric layer stack), Al₂O₃/SiO₂/Si₃N₄/SiO₂ (e.g. a four dielectric layer stack), or a dielectric stack comprising other appropriate dielectric layers. Dielectric region 216 has thickness 220, which can be between approximately 50.0 Angstroms and approximately 200.0 Angstroms, for example.

Further shown in FIG. 2, wordline segment 214, which is a segment of wordline 202b, is situated over dielectric region 216 and can comprise an N type semiconductor, such as N type polycrystalline silicon. Wordline segment 214, which forms a gate of memory cell 206, can have an N+ type dopant concentration of between approximately 1.0×10¹⁸ cm⁻³ and approximately 1.0×10²⁰ cm⁻³. Thus, memory cell 206, which is situated at the intersection of wordline 202b and bitline 204c, includes wordline segment 214 (i.e. an N type semiconductor) and dielectric region 216, which is sandwiched between wordline segment 214 of wordline 202b and bitline 204c.

The programming of memory cell 206, which is an exemplary memory cell in the present invention's programmable ROM array (e.g. programmable ROM array 101 in FIG. 1), will now be discussed. During the programming of memory cell 206, wordline 102b is biased at a negative voltage (i.e. a negative voltage is applied to wordline 102b) and bitline 204c is biased at a positive voltage (i.e. a positive voltage is applied to bitline 204c). The negative and positive voltages are selected such that the difference between the positive and negative voltages is sufficient to cause only dielectric region 216 of memory cell 206 to break down. In other words, the negative and positive voltages that are applied to respective wordline 102b and bitline 204c during programming of memory cell 206 do not cause the dielectric regions of other respective memory cells in programmable ROM array 101 to break down. During programming of memory cell 206, the other wordlines in programmable ROM array 101 are floating while the other bitlines in programmable ROM array 101 are held at 0.0 volts.

The specific values of the voltages that are applied to wordline 202b and bitline 204c during the programming of memory cell 206 are determined by thickness 220 of dielectric region 216. By way of example, during programming of memory cell 206, the voltage on wordline 202b can be −15.0 volts +30% and the voltage on bitline 204c can be +15.0 volts +30% for a thickness (i.e. thickness 220) of dielectric region 216 of between approximately 50.0 Angstroms and approximately 200.0 Angstroms. For high voltage applications, thickness 220 can be appropriately increased, while for low voltage applications, thickness 220 can be appropriately decreased.

After the breakdown of dielectric region 216, memory cell 206 operates as a “PN” junction diode (hereinafter a “diode'). Thus, as a result of the breakdown of dielectric region 216 during the programming operation, memory cell 206 operates as a diode, which has an anode and a cathode comprising respective bitline 204c (i.e. a P type semiconductor) and wordline segment 214 of wordline 202b (i.e. an N type semiconductor). After dielectric region 216 has been broken down during the programming operation, memory cell 206 can have a forward bias resistance of less than 10.0 Ohms, for example, as measured between wordline 202b and bitline 204c. In contrast, prior to breakdown of dielectric region 216, memory cell 206 can have a resistance than is greater than 10.0 Kilo Ohms, for example.

Thus, since the resistance of memory cell 206 is substantially lower after dielectric region 216 has been broken down compared to the resistance of memory cell 206 prior to breakdown of dielectric region 216, the logic state of memory cell 206 can be defined by the resistance of memory cell 206 (as measured between wordline 202b and bitline 204c). For example, the logic state of memory cell 206 might be defined as a logic “0” state before breakdown of dielectric region 216 and as a logic “1” state after breakdown of dielectric region 216. Thus, programming of memory cell 206 causes dielectric region 216 to breakdown, thereby causing the logic state of memory cell 206 to change from a logic “0” state to a logic “1” state, or vice versa.

During performance of a read operation on memory cell 206, only memory cell 206 is forward biased. Thus, by measuring the resistance of memory cell 206 during a read operation, the logic state of memory cell 206 (i.e. whether memory cell 206 has a logic “0” state or a logic “1” state) can be determined. By way of example, during reading of memory cell 206, the voltage on wordline 202b can be −1.0 volt +20%, the voltage on bitline 204c can be +1.0 volt ±20%, the voltage on other wordlines (e.g. wordlines 102a, 102c, and 102d) in programmable ROM array 101 can be +1.0 volt +20%, and the voltage on other bitlines (e.g. bitlines 104a, 104b, 104d, and 104e) in the programmable ROM array can be −1.0 volt +20%.

FIG. 3 shows a diagram of an exemplary memory cell in an exemplary programmable ROM array after a programming operation, in accordance with one embodiment of the present invention. In diagram 300, memory cell 306, wordline segment 314, and bitline 304 correspond, respectively, to memory cell 206, wordline segment 214, and bitline 204c in structure 200 in FIG. 2. Diagram 300 includes memory cell 306, ground 322, and gate voltage (Vg) 324. Memory cell 306 includes wordline segment 314 (i.e. an N type semiconductor) and dielectric region 316.

As shown in FIG. 3, wordline segment 314, which comprises a gate of memory cell 306, is coupled to gate voltage 324, and bitline 304 is coupled to ground 322. Also shown in FIG. 3, dielectric region 316 is situated between wordline segment 314 (i.e. a gate) and bitline 304. During a programming operation, gate voltage 324 is applied to wordline segment 314 at a sufficient voltage level so as to cause dielectric region 316 to break down. When dielectric region 316 breaks down, current paths 326 are formed in dielectric region 316, which allows gate current (Ig) 328 to flow from wordline segment 314 (i.e. a gate of memory cell 306) through dielectric region 316 and bitline 304 to ground 322.

Thus, after dielectric region 316 has been broken down in the programming operation, wordline segment 314 (i.e. an N type semiconductor) is electrically connected to bitline 304 (i.e. a P type semiconductor) while remaining physically separated. Since wordline segment 314 is electrically connected to bitline 304 after dielectric region 316 has been broken down, memory cell 306 operates as a diode (i.e. a “PN” junction diode). Thus, memory cell 306 has a low forward bias resistance after breakdown of dielectric region 316 and a substantially higher resistance prior to breakdown of dielectric region 316. As a result, the substantially higher resistance of a memory cell in the invention's programmable ROM array prior to breakdown of the memory cell's dielectric region advantageously defines a logic state, such as a logic “0” state, while the substantially lower forward bias resistance of the memory cell after dielectric region breakdown advantageously defines an opposite logic state, such as a logic “1” state.

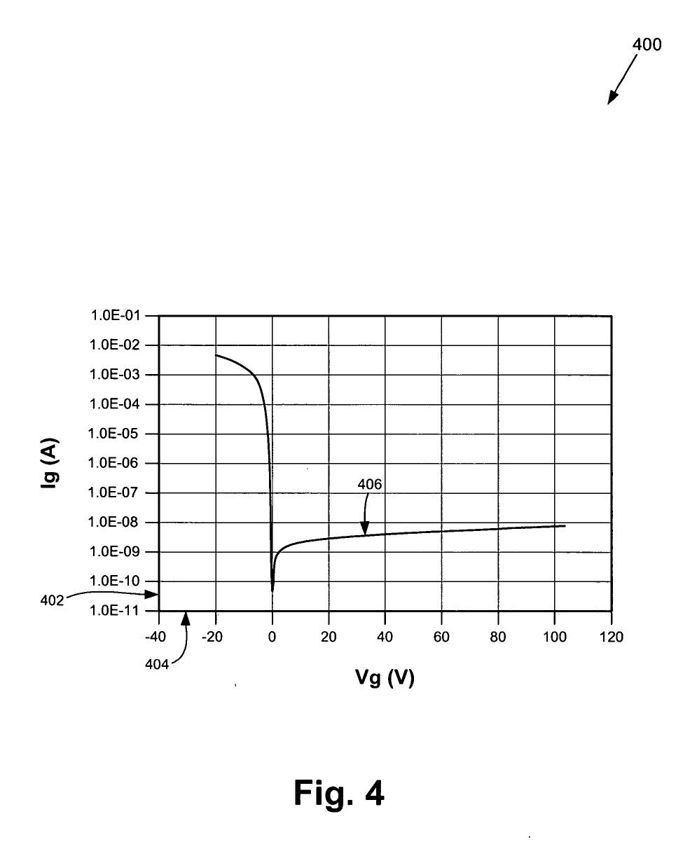

FIG. 4 shows exemplary graph 400 including an exemplary I-V curve of an exemplary memory cell in accordance with one embodiment of the present invention. Graph 400 includes current axis 402, voltage axis 404, and I-V curve 406. In graph 400, current axis 402 corresponds to an exemplary gate current range of between 1.0×10⁻¹¹ amperes and 1.0×10⁻¹ amperes and voltage axis 404 corresponds to an exemplary gate voltage range of between −40.0 volts and 120.0 volts. It is noted that in graph 400, gate current is indicated as an absolute value. In graph 400, I-V curve 406 corresponds to the I-V characteristics of a memory cell (e.g. memory cell 306 in FIG. 3) in the invention's programmable ROM array (e.g. programmable ROM array 101 in FIG. 1), after breakdown of a dielectric region (e.g. dielectric region 316) in the memory cell.

In the example shown in graph 400, I-V curve 406 exhibits I-V characteristics that are similar to the I-V characteristics of a diode (i.e. a “PN” junction diode). Thus, by causing the dielectric region (e.g. dielectric region 316) of a memory cell (e.g. memory cell 306) to break down during a programming operation, the present invention achieves a memory cell that operates as a diode after dielectric region breakdown. As a result, the forward-bias resistance of the memory cell in the present invention is substantially lower (e.g. less than 10.0 Ohms) after breakdown of the dielectric region compared to the resistance of the memory cell prior to dielectric region breakdown (e.g. greater than 10.0 Kilo Ohms). As a result, the logic state of a memory cell in the present invention's programmable ROM array can be advantageously determined by measuring the forward-bias resistance of the memory cell during a read operation.

Thus, by forming a programmable ROM array by utilizing breakdown of dielectric regions of respective memory cells, the present invention advantageously achieves a programmable ROM array that has high performance, high scalability, and that can operate under a wide range of voltages. Also, the present invention's programmable ROM array is easy to implement and is fully compatible with existing silicon processing technologies.

In other embodiments, a multi-level programmable ROM array can be implemented by stacking a desired number of the invention's programmable ROM arrays (e.g. programmable ROM array 101 in FIG. 1). As a result, the present invention can advantageously achieve a multi-level programmable ROM array having substantially increased memory cell density.

From the above description of exemplary embodiments of the invention it is manifest that various techniques can be used for implementing the concepts of the present invention without departing from its scope. Moreover, while the invention has been described with specific reference to certain embodiments, a person of ordinary skill in the art would recognize that changes could be made in form and detail without departing from the spirit and the scope of the invention. The described exemplary embodiments are to be considered in all respects as illustrative and not restrictive. It should also be understood that the invention is not limited to the particular exemplary embodiments described herein, but is capable of many rearrangements, modifications, and substitutions without departing from the scope of the invention.

Thus, a read-only memory array with dielectric breakdown programmability has been described.

1. A programmable ROM array comprising:
at least one bitline situated in a substrate;
at least one wordline situated over said at least one bitline;
a memory cell situated at an intersection of said at least one bitline and said at least one wordline, said memory cell comprising a dielectric region situated between said at least one bitline and said at least one wordline;
wherein a programming operation causes said memory cell to change from a first logic state to a second logic state by causing said dielectric region to break down.

2. The programmable ROM array of claim 1 wherein a difference between a first voltage applied to said at least one wordline and a second voltage applied to said at least one bitline during said programming operation causes said dielectric region to break down.

3. The programmable ROM array of claim 1 wherein said programming operation causes said memory cell to operate as a diode.

4. The programmable ROM array of claim 1 wherein said at least one wordline comprises an N type semiconductor.

5. The programmable ROM array of claim 4 wherein said N type semiconductor has an N type dopant concentration of between approximately 1.0×10¹⁸ cm⁻³ and approximately 1.0×10²⁰ cm⁻³.

6. The programmable ROM array of claim 1 wherein said at least one bitline comprises a P type semiconductor.

7. The programmable ROM array of claim 1 wherein said dielectric region has a thickness of between approximately 50.0 Angstroms and approximately 200.0 Angstroms.

8. The programmable ROM array of claim 1 wherein a resistance of said memory cell is measured in a read operation to determine if said memory cell has said first logic state or said second logic state.

9. The programmable ROM array of claim 1 wherein said dielectric region comprises a single layer of dielectric material, wherein said dielectric material is selected from the group consisting of silicon oxide, aluminum oxide, hafnium oxide, silicon nitride, zirconium oxide, and titanium oxide.

10. The programmable ROM array of claim 1 wherein said dielectric region comprises an ONO stack.

11. A programmable ROM array comprising:
at least one bitline situated in a substrate, said at least one bitline comprising a P type semiconductor;
at least one wordline situated over said at least one bitline, said at least one wordline comprising an N type semiconductor;
a memory cell situated at an intersection of said at least one bitline and said at least one wordline, said memory cell comprising a dielectric region situated between said at least one bitline and said at least one wordline;
wherein a programming operation causes said memory cell to change from a first logic state to a second logic state by causing said dielectric region to break down, and wherein said programming operation causes said memory cell to operate as a diode.

12. The programmable ROM array of claim 11 wherein a difference between a first voltage applied to said at least one wordline and a second voltage applied to said at least one bitline during said programming operation causes said dielectric region to break down.

13. The programmable ROM array of claim 11 wherein said N type semiconductor has an N type dopant concentration of between approximately 1.0×10¹⁸ cm⁻³ and approximately 1.0×10²⁰ cm⁻³.

14. The programmable ROM array of claim 11 wherein said dielectric region has a thickness of between approximately 50.0 Angstroms and approximately 200.0 Angstroms.

15. The programmable ROM array of claim 11 wherein a resistance of said memory cell is measured in a read operation to determine if said memory cell comprises said first logic state or said second logic state.

16. The programmable ROM array of claim 11 wherein said dielectric region comprises a single layer of dielectric material.

17. The programmable ROM array of claim 16 wherein said dielectric material is selected from the group consisting of silicon oxide, aluminum oxide, hafnium oxide, silicon nitride, zirconium oxide, and titanium oxide.

18. The programmable ROM array of claim 11 wherein said dielectric region comprises an ONO stack.

19. The programmable ROM array of claim 11 wherein a resistance of said memory cell is greater than 10.0 Kilo Ohms in said first logic state.

20. The programmable ROM array of claim 11 wherein said memory cell has a forward bias resistance of less than 10.0 Ohms in said second logic state.
